(19) United States
(12) Patent Application Publication
(10) Pub. No.: US 2026/0208245 A1
(43) Pub. Date: Jul. 23, 2026

(54) System and Method for Fastener Removal

(71) Applicant: Carnegie Mellon University, Pittsburgh, PA (US)

(72) Inventors: Matthew Travers, Pittsburgh, PA (US); Ralph Boirum, Pittsburgh, PA (US)

(21) Appl. No.: 19/452,506

(22) Filed: Jan. 19, 2026

Related U.S. Application Data
(60) Provisional application No. 63/747,152, filed on Jan. 20, 2025.

(51) Int. Cl. B09B 3/35; B09B 101/15; B25J 11/00; H05K 3/22

(52) U.S. Cl. CPC B09B 3/35; B25J 11/0055; B09B 2101/15; H05K 3/22; H05K 2203/178

(57) ABSTRACT

Provided is a system and method for removing fasteners. The system includes a sensor, a punch device, and at least one processor in communication with the sensor and the punch device, the at least one processor configured to detect a plurality of fasteners on an object based on the sensor, determine a location of each fastener of the plurality of fasteners, and control the punch device to automatically punch through the object with the punch device at each location for each of the plurality of fasteners.

### CROSS REFERENCE TO RELATED APPLICATION

The present application claims the benefit of U.S. Provisional Patent Application No. 63/747,152, filed Jan. 20, 2025, the disclosure of which is hereby incorporated by reference in its entirety.

### BACKGROUND

### 1. Field

This disclosure relates generally to fastener removal and, in non-limiting embodiments, to systems and methods for removing fasteners from devices and/or objects.

### 2. Technical Considerations

Electronic waste is often remediated and recycled manually, including disassembly of electronic devices and other objects. Existing methods for disassembling electronic devices are labor intensive and slow, requiring various special tools and considerations for different types of devices.

### SUMMARY

According to non-limiting embodiments or aspects, provided is a system comprising: a sensor; a punch device; and at least one processor in communication with the sensor and the punch device, the at least one processor configured to: detect a plurality of fasteners on an object based on the sensor; determine a location of each fastener of the plurality of fasteners; and control the punch device to automatically punch through the object with the punch device at each location for each of the plurality of fasteners.

In non-limiting embodiments or aspects, the system may include an end effector configured to move the punch device in at least three dimensions, the at least one processor further configured to control movement of the end effector to punch through the object at each location. In non-limiting embodiments or aspects, the end effector is arranged on a routing machine and/or a robotic arm. In non-limiting embodiments or aspects, the system may include a consumable surface arranged below the object, the consumable surface adapted to be punctured by at least a subset of fasteners punched with a punching device. In non-limiting embodiments or aspects, the system may include a conveyer belt arranged to convey a plurality of objects including the object across an area, the punch device is arranged to punch objects in the area. In non-limiting embodiments or aspects, the at least one processor is further configured to: generate at least one graphical user interface based on detecting the plurality of fasteners, the at least one graphical user interface comprising visual representations of at least a subset of fasteners of the plurality of fasteners; and receive user input through the at least one graphical user interface, wherein punching through the object with the punch device is based on the user input. In non-limiting embodiments or aspects, the user input comprises a confirmation of a fastener location and/or a rejection of a fastener location, and the object is punched in response to receiving the user input. In non-limiting embodiments or aspects, the plurality of fasteners is detected based on a fastener detection model, and the at least one processor is further configured to train the fastener detection model based on the user input. In non-limiting embodiments or aspects, the sensor comprises a camera, and the plurality of fasteners is detected based on processing data from the camera with an object detection model. In non-limiting embodiments or aspects, the location of each fastener is determined based on calibration data and sensor data received from the sensor.

According to non-limiting embodiments or aspects, provided is a method comprising: detecting, with at least one processor, a plurality of fasteners on an object based on sensor data received from a sensor arranged to capture visual data of the object; determining, with at least one processor, a location of each fastener of the plurality of fasteners based on the sensor data; and control a punch device to automatically punch through the object with the punch device at each location for each of the plurality of fasteners.

In non-limiting embodiments or aspects, the punch device is supported by an end effector configured to move the punch device in at least three dimensions, the method further includes controlling movement of the end effector to punch through the object at each location. In non-limiting embodiments or aspects, the end effector is arranged on a routing machine and/or a robotic arm. In non-limiting embodiments or aspects, the method further includes arranging a consumable surface below the object, the consumable surface adapted to be punctured by at least a subset of fasteners punched with a punching device. In non-limiting embodiments or aspects, the method further includes conveying, with a conveyor belt, a plurality of objects including the object across an area, the punch device is arranged to punch objects in the area. In non-limiting embodiments or aspects, the method further includes generating at least one graphical user interface based on detecting the plurality of fasteners, the at least one graphical user interface comprising visual representations of at least a subset of fasteners of the plurality of fasteners; and receiving user input through the at least one graphical user interface, wherein punching through the object with the punch device is based on the user input. In non-limiting embodiments or aspects, the user input comprises a confirmation of a fastener location and/or a rejection of a fastener location, and the object is punched in response to receiving the user input. In non-limiting embodiments or aspects, the plurality of fasteners is detected based on a fastener detection model, the method further includes training the fastener detection model based on the user input. In non-limiting embodiments or aspects, the sensor comprises a camera, and the plurality of fasteners is detected based on processing data from the camera with an object detection model. In non-limiting embodiments or aspects, the location of each fastener is determined based on calibration data and sensor data received from the sensor.

According to non-limiting embodiments or aspects, provided is a computer program product comprising at least one non-transitory computer-readable medium including program instructions that, when executed by at least one processor in communication with a sensor and a punch device, cause the processor to perform the steps of the methods described above.

Other preferred and non-limiting embodiments or aspects of the present invention will be set forth in the following numbered clauses:

Clause 1: A system comprising: a sensor; a punch device; and at least one processor in communication with the sensor and the punch device, the at least one processor configured to: detect a plurality of fasteners on an object based on the sensor; determine a location of each fastener of the plurality of fasteners; and control the punch device to automatically punch through the object with the punch device at each location for each of the plurality of fasteners.

Clause 2: The system of clause 1, further comprising an end effector configured to move the punch device in at least three dimensions, the at least one processor further configured to control movement of the end effector to punch through the object at each location.

Clause 3: the system of clause 1 or 2, wherein the end effector is arranged on a routing machine and/or a robotic arm.

Clause 4: The system of any of clauses 1-3, further comprising a consumable surface arranged below the object, the consumable surface adapted to be punctured by at least a subset of fasteners punched with a punching device.

Clause 5: The system of any of clauses 1-4, further comprising a conveyer belt arranged to convey a plurality of objects including the object across an area, wherein the punch device is arranged to punch objects in the area.

Clause 6: The system of any of clauses 1-5, wherein the at least one processor is further configured to: generate at least one graphical user interface based on detecting the plurality of fasteners, the at least one graphical user interface comprising visual representations of at least a subset of fasteners of the plurality of fasteners; and receive user input through the at least one graphical user interface, wherein punching through the object with the punch device is based on the user input.

Clause 7: The system of any of clauses 1-6, wherein the user input comprises a confirmation of a fastener location and/or a rejection of a fastener location, and wherein the object is punched in response to receiving the user input.

Clause 8: The system of any of clauses 1-7, wherein the plurality of fasteners is detected based on a fastener detection model, and wherein the at least one processor is further configured to train the fastener detection model based on the user input.

Clause 9: The system of any of clauses 1-8, wherein the sensor comprises a camera, and wherein the plurality of fasteners is detected based on processing data from the camera with an object detection model.

Clause 10: The system of any of clauses 1-9, wherein the location of each fastener is determined based on calibration data and sensor data received from the sensor.

Clause 11: A method comprising: detecting, with at least one processor, a plurality of fasteners on an object based on sensor data received from a sensor arranged to capture visual data of the object; determining, with at least one processor, a location of each fastener of the plurality of fasteners based on the sensor data; and control a punch device to automatically punch through the object with the punch device at each location for each of the plurality of fasteners.

Clause 12: The method of clause 11, wherein the punch device is supported by an end effector configured to move the punch device in at least three dimensions, the method further comprising controlling movement of the end effector to punch through the object at each location.

Clause 13: The method of clause 11 or 12, wherein the end effector is arranged on a routing machine and/or a robotic arm.

Clause 14: The method of any of clauses 11-13, further comprising a consumable surface arranged below the object, the consumable surface adapted to be punctured by at least a subset of fasteners punched with a punching device.

Clause 15: The method of any of clauses 11-14, the method further comprising conveying, with a conveyor belt, a plurality of objects including the object across an area, wherein the punch device is arranged to punch objects in the area.

Clause 16: The method of any of clauses 11-15, the method further comprising: generating at least one graphical user interface based on detecting the plurality of fasteners, the at least one graphical user interface comprising visual representations of at least a subset of fasteners of the plurality of fasteners; and receiving user input through the at least one graphical user interface, wherein punching through the object with the punch device is based on the user input.

Clause 17: The method of any of clauses 11-16, wherein the user input comprises a confirmation of a fastener location and/or a rejection of a fastener location, and wherein the object is punched in response to receiving the user input.

Clause 18: The method of any of clauses 11-17, wherein the plurality of fasteners is detected based on a fastener detection model, the method further comprising training the fastener detection model based on the user input.

Clause 19: The method of any of clauses 11-18, wherein the sensor comprises a camera, and wherein the plurality of fasteners is detected based on processing data from the camera with an object detection model.

Clause 20: The method of any of clauses 11-19, wherein the location of each fastener is determined based on calibration data and sensor data received from the sensor.

Clause 21: A computer program product comprising at least one non-transitory computer-readable medium including program instructions that, when executed by at least one processor in communication with a sensor and a punch device, cause the processor to perform the methods of any of clauses 11-20.

These and other features and characteristics of the present disclosure, as well as the methods of operation and functions of the related elements of structures and the combination of parts and economies of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for the purpose of illustration and description only and are not intended as a definition of the limits of the invention.

### BRIEF DESCRIPTION OF THE DRAWINGS

Additional advantages and details are explained in greater detail below with reference to the non-limiting, exemplary embodiments that are illustrated in the accompanying figures shown in the separate attachment, in which:

FIG. 1 is a schematic diagram of a fastener removal system according to non-limiting embodiments or aspects;

FIG. 2 is a flow diagram for a method of removing fasteners according to non-limiting embodiments or aspects;

FIG. 3 illustrates example components of a computing device used in connection with non-limiting embodiments or aspects; and

FIGS. 4-6 are illustrations of a fastener removal system according to non-limiting embodiments or aspects.

### DETAILED DESCRIPTION

It is to be understood that the embodiments may assume various alternative variations and step sequences, except where expressly specified to the contrary. It is also to be understood that the specific devices and processes described in the following specification are simply exemplary embodiments or aspects of the disclosure. Hence, specific dimensions and other physical characteristics related to the embodiments or aspects disclosed herein are not to be considered as limiting. No aspect, component, element, structure, act, step, function, instruction, and/or the like used herein should be construed as critical or essential unless explicitly described as such. Also, as used herein, the articles “a” and “an” are intended to include one or more items and may be used interchangeably with “one or more” and “at least one.” Also, as used herein, the terms “has,” “have,” “having,” or the like are intended to be open-ended terms. Further, the phrase “based on” is intended to mean “based at least partially on” unless explicitly stated otherwise.

As used herein, the terms “communication” and “communicate” refer to the receipt or transfer of one or more signals, messages, commands, or other type of data. For one unit (e.g., any device, system, or component thereof) to be in communication with another unit means that the one unit is able to directly or indirectly receive data from and/or transmit data to the other unit. This may refer to a direct or indirect connection that is wired and/or wireless in nature. Additionally, two units may be in communication with each other even though the data transmitted may be modified, processed, relayed, and/or routed between the first and second unit. For example, a first unit may be in communication with a second unit even though the first unit passively receives data and does not actively transmit data to the second unit. As another example, a first unit may be in communication with a second unit if an intermediary unit processes data from one unit and transmits processed data to the second unit. It will be appreciated that numerous other arrangements are possible.

As used herein, the terms “processor” or “computing device” may refer to one or more electronic devices configured to process data. A processor and/or computing device may include, for example, a Central Processing Unit (CPU), a Graphics Processing Unit (GPU), a microprocessor, a controller, and/or any other computational device capable of executing logic. A “computer readable medium” may refer to one or more memory devices or other non-transitory storage mechanisms capable of storing compiled or non-compiled program instructions for execution by one or more processors. Reference to “a processor” or “a computing device” as used herein, may refer to a previously-recited computing device and/or processor that is recited as performing a previous step or function, a different server and/or processor, and/or a combination of computing devices and/or processors. For example, as used in the specification and the claims, a first computing device and/or a first processor that is recited as performing a first step or function may refer to the same or different computing device and/or a processor recited as performing a second step or function.

As used herein, the term “fastener” may refer to any device or structure used to attach two or more components. For example, a fastener may include a screw, bolt, rivet, nail, adhesive, and/or the like.

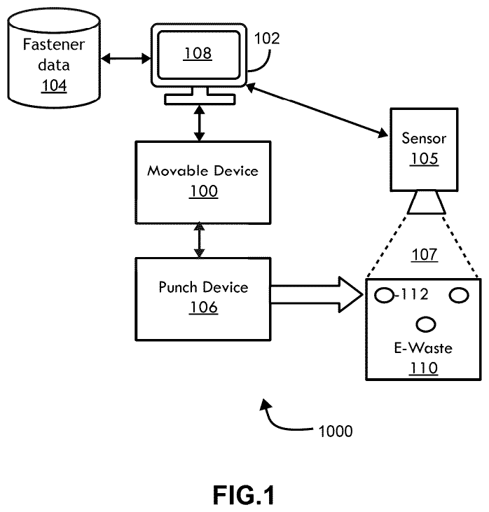

Referring to FIG. 1, a fastener removal system 1000 is shown according to non-limiting embodiments. The fastener removal system 1000 is configured to remove fasteners 112 by pushing them through an object 110 (such as electronic waste) using pressure and force. Non-limiting embodiments allow for the fast and efficient removal of fasteners 112 from devices and objects, such as televisions, hard drives, computing devices, circuit boards, and/or the like.

In non-limiting embodiments, a fastener removal system 1000 may include at least one sensor arranged 105 with a field of view 107 including an area capable of receiving an object 110 with fasteners 112. The sensor 105 may include, for example, one or more cameras in communication with a computing device 102. In non-limiting embodiments, stereo vision cameras may be used. It will be appreciated that various types of cameras or other visual sensors may be used. The system 1000 may include one or more computing devices 102 for performing the processes described herein. A single computing device 102 is shown in FIG. 1 for explanation purposes only.

The sensor 105 and computing device 102 may be configured to detect one or more fasteners in the field of view 107 of the sensor 105 and/or in the coordinate frame of a movable device 100 using one or more object detection algorithms. The detection may occur while the object is stationary or while the object is being conveyed on a conveyor belt with other objects. The fasteners 112 may be detected using a machine-learning model trained to detect fasteners in the image data based on supervised training, as an example. It will be appreciated that various types of algorithms, models, and/or training data may be used in non-limiting embodiments.

In non-limiting embodiments, after the plurality of fasteners are detected, the computing device 102 may determine a location of each fastener 112. The location may be determined in spatial coordinates (e.g., x, y, z) for a region that includes the coordinate frame of the movable device 100. The location may be based on a calibration of the sensor 105 to map each fastener 112 detected by the sensor 105 to at least an x and y coordinate from a reference point. In non-limiting embodiments the depth of the fastener 112 may be used as a z coordinate. In non-limiting examples, a calibration process may be performed by physically moving a punch device 106 over one or more fasteners 112 after the sensor data is collected, allowing the computing device 102 to correspond the coordinates of the punch device 106 with the coordinates of the detected fastener 112.

The locations of the fasteners 112 in the coordinate frame are then communicated to a movable device 100, such as a router (e.g., routing machine), robotic arm, and/or the like. For example, the locations may be communicated to a tooling mast of a router or other like device that moves an end effector to the location.

Once the locations (e.g., coordinates) of each fastener 112 are known, a punch device 106 may be controlled to punch through the object at the location to kinematically remove the fastener from the surrounding housing or other materials of the object 110. For example, kinematic removal of the fastener may include pushing the fastener through the object 110. In non-limiting embodiments, a punch device 106 may be arranged on the movable device 100 or an end effector thereof such that it can be moved in two or three dimensions. As used herein, a “punch device” is a device that outputs a high pressure of gas (e.g., air) and/or liquid (e.g., water) to perforate a surface or object 110. A punch device may include a pneumatic punch (e.g., pneumatic gun), a hydraulic punch, and/or the like.

In non-limiting embodiments, multiple passes of the same object may be performed to remove layers of housings, circuit boards, and/or the like.

In non-limiting embodiments, the movable device 100 is fixed with respect to a conveyor belt (not shown in FIG. 1) that conveys electronic waste or other objects toward the field of view 107 of the sensor 105 and the coordinate frame of the movable device 100, which may be spatially separate or overlapped. For example, in some non-limiting embodiments the sensor may collect visual data in a first location and remove the fasteners in a second location, such as on two different locations of a conveyor. In some non-limiting embodiments the collection of visual data and the removal of fasteners may occur in the same location.

In some non-limiting embodiments, the punch device 106 may be in a fixed location and the movable device 100 may instead move the object 110 to arrange the fasteners with respect to the punch device 106.

In non-limiting embodiments, a surface, such as a table, platform, and/or the like, may be arranged under the object 110 and/or conveyor belt. The surface may be formed from a consumable material, such as wood, rubber, plastic, and/or the like, that can at least partially absorb or receive a projectile such as a fastener being forced through an object. In this manner the fastener and any other piece of the object that the fastener is removed with does not ricochet or reenter the object because the surface is made of a material that does not partially absorb or receive the fastener, such as a hard metal and/or other like material.

In non-limiting embodiments, the system 1000, including the computing device(s) 102, controls internal processes and components, provides a graphical user interface (GUI) 108 to the operator, and learns to optimize the performance of the system by collecting and storing data and using the data to train one or more machine-learning algorithms for detecting the fasteners and/or determining the location coordinates of the fasteners.

In non-limiting embodiments, the computing device generates one or more GUIs 108 to facilitate operation of the system. The GUI 108 may show a visual representation of the object including the detected fasteners. For example, each fastener may be visually augmented on an image of the object displayed on the GUI 108 with highlighting, boxes, circles, icons, and/or the like. The operator may interact with the GUI 108 to select one or more fasteners. For example, the operator may select or touch each visual representation to confirm a fastener is in that location or to reject a fastener shown in that location. In some examples, the operator may select fasteners before they are visually augmented on the GUI 108. In some examples, the operator may select fasteners that are not visually augmented on the GUI 108 even where other fasteners are augmented. This interaction data may be collected and stored as supervised training data (e.g., fastener data 104) to train and/or optimize the machine-learning model used to detect the fasteners and/or other models or algorithms used to automate the process. The fastener data 104 may be stored in one or more data storage devices in communication with the computing device.

In non-limiting embodiments, the GUI 108 may present one or more options to affect the fastener removal process. For example, a user may define system behaviors such as calibration, pressure, speed, and/or the like.

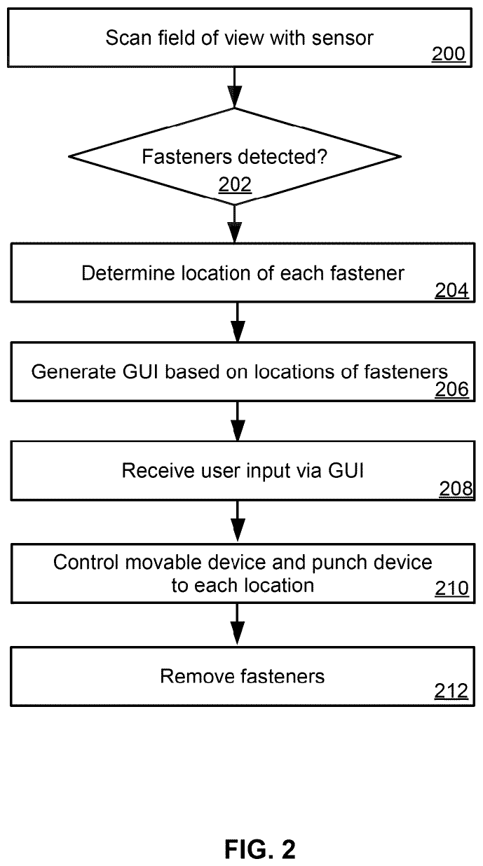

Referring now to FIG. 2, shown is a flow diagram for a method of manufacturing according to some non-limiting embodiments or aspects. The steps shown in FIG. 2 are for example purposes only. It will be appreciated that additional, fewer, different, and/or a different order of steps may be used in some non-limiting embodiments or aspects. In some non-limiting embodiments or aspects, a step may be automatically performed in response to performance and/or completion of a prior step. One or more steps may be performed by the same or different computing devices. At step 200, a field of view is scanned with a sensor to detect one or more fasteners on an object within the field of view. For example, one or more images may be captured with a camera. At step 202, it is determined if there are any fasteners detected in the image using an image detection algorithm, such as a machine-learning model. If there are no fasteners detected, the method may proceed to step 200 to scan a new object and/or to scan the same object again. If there are fasteners detected, the method may proceed to step 204.

At step 204, a location is determined for each detected fastener. The locations may be determined by correlating the visual information from the sensors with the spatial coordinates of a movable device, such as a router or robotic arm. As an example, three-dimensional coordinates may be determined for each fastener within the coordinate system of the movable device. At step 206, the locations are visually displayed on a GUI that is accessible to an operator. At step 208, user input is received via the GUI to confirm the locations of the fasteners, reject the locations of the fasteners, modify the locations of the fasteners, and/or the like. This input may be stored for optimization and/or training of the machine-learning model used at step 202 and/or location determination of step 204. At step 210, the punch device is moved to each location of each fastener and at step 212 automatically punches through the object at each location to remove the fastener.

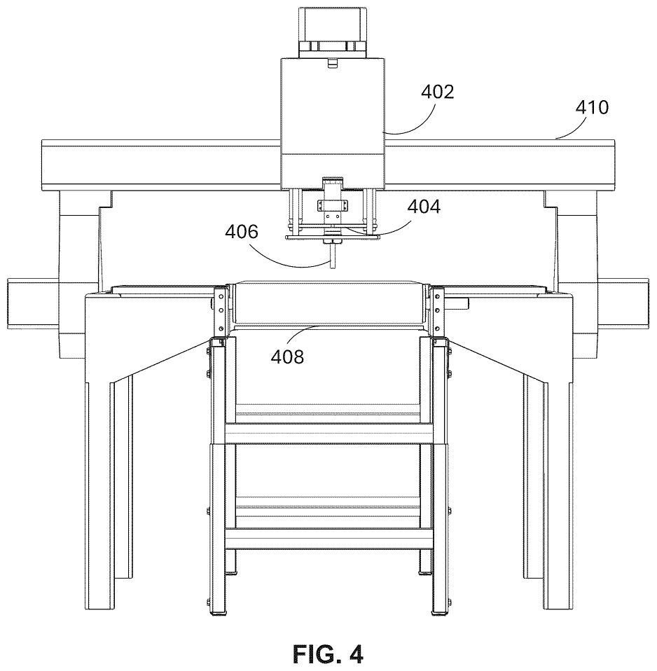

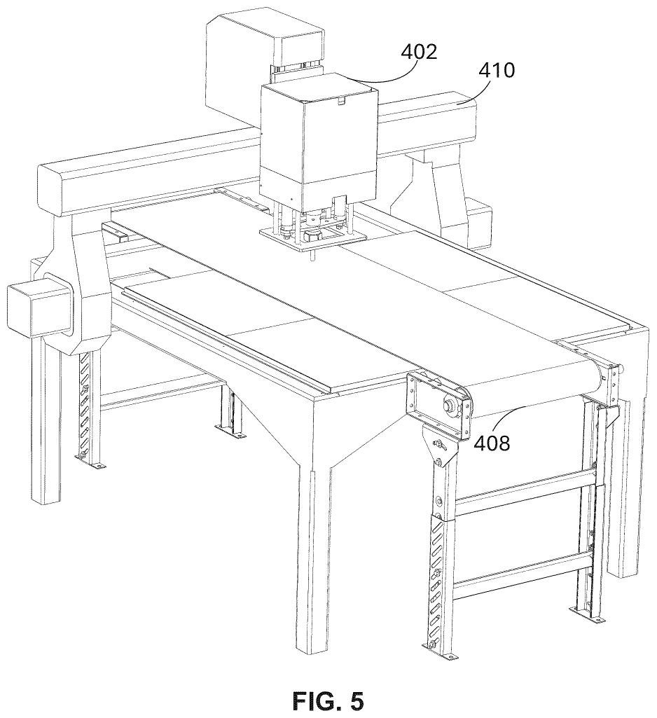

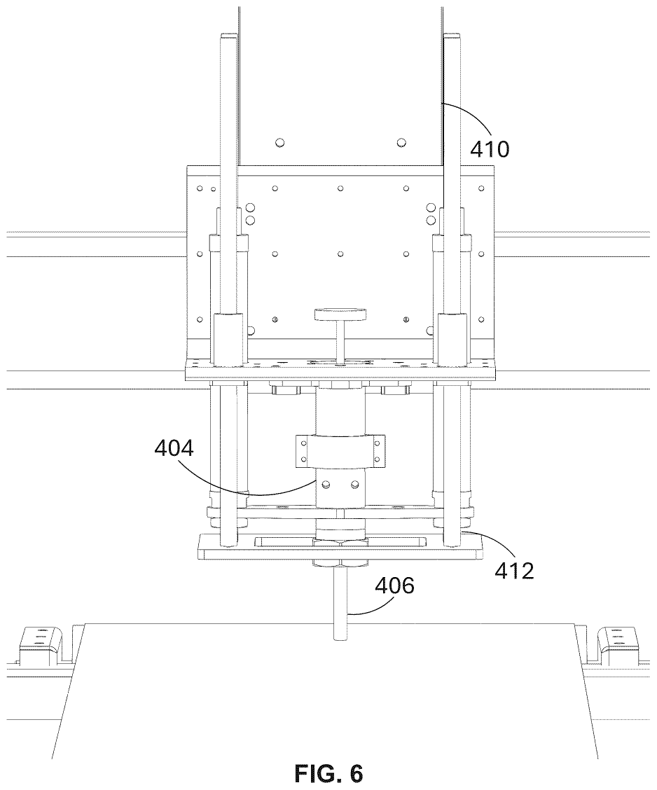

Referring now to FIGS. 4-6, non-limiting embodiments of a fastener removal system 4000 are shown. FIG. 4 shows a front view of a fastener removal system according to non-limiting embodiments, FIG. 5 shows a perspective view of a fastener removal system according to non-limiting embodiments, and FIG. 6 shows a front view of a movable device 404 and end effector 412. In the example shown in FIGS. 4-6, a router 410 is used to control a movable device 402 of the router 410 and a punching device 404 having a nozzle 406 arranged on the movable device 402. The nozzle 406 is located above a conveyor belt 408 that conveys objects to be processed for fastener removal. It will be appreciated that in other non-limiting embodiments the nozzle 406 may be located at other angles with respect to the object being processed. FIG. 6 shows an end effector 412 used to support the punching device 406. As shown, the end effector 412 includes springs and/or other force-absorbing materials and/or mechanisms to absorb a force from operation of the punching device 406 without affecting the position or structure of the movable device 410.

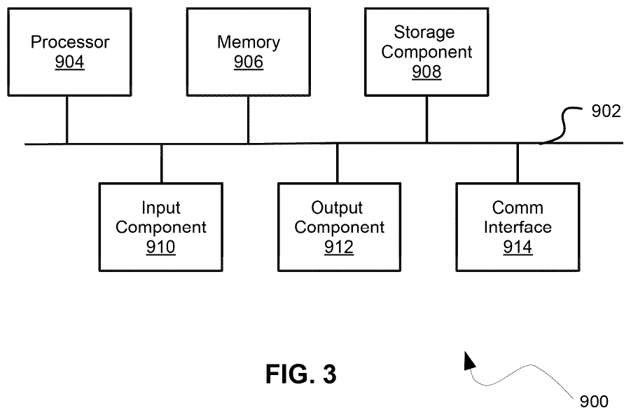

Referring now to FIG. 3, shown is a diagram of example components of a computing device 900 for implementing and performing the systems and methods described herein according to non-limiting embodiments. For example, the computing device 900 may correspond to the computing device(s) described herein. In some non-limiting embodiments, device 900 may include additional components, fewer components, different components, or differently arranged components than those shown in FIG. 3. Device 900 may include a bus 902, a processor 904, memory 906, a storage component 908, an input component 910, an output component 912, and a communication interface 914. Bus 902 may include a component that permits communication among the components of device 900. In some non-limiting embodiments, processor 904 may be implemented in hardware, firmware, or a combination of hardware and software. For example, processor 904 may include a processor (e.g., a central processing unit (CPU), a graphics processing unit (GPU), an accelerated processing unit (APU), etc.), a microprocessor, a digital signal processor (DSP), and/or any processing component (e.g., a field-programmable gate array (FPGA), an application-specific integrated circuit (ASIC), etc.) that can be programmed to perform a function. Memory 906 may include random access memory (RAM), read only memory (ROM), and/or another type of dynamic or static storage device (e.g., flash memory, magnetic memory, optical memory, etc.) that stores information and/or instructions for use by processor 904.

With continued reference to FIG. 3, storage component 908 may store information and/or software related to the operation and use of device 900. For example, storage component 908 may include a hard disk (e.g., a magnetic disk, an optical disk, a magneto-optic disk, a solid state disk, etc.) and/or another type of computer-readable medium. Input component 910 may include a component that permits device 900 to receive information, such as via user input (e.g., a touch screen display, a keyboard, a keypad, a mouse, a button, a switch, a microphone, etc.). Additionally, or alternatively, input component 910 may include a sensor for sensing information (e.g., a photo-sensor, a thermal sensor, an electromagnetic field sensor, a global positioning system (GPS) component, an accelerometer, a gyroscope, an actuator, etc.). Output component 912 may include a component that provides output information from device 900 (e.g., a display, a speaker, one or more light-emitting diodes (LEDs), etc.). Communication interface 914 may include a transceiver-like component (e.g., a transceiver, a separate receiver and transmitter, etc.) that enables device 900 to communicate with other devices, such as via a wired connection, a wireless connection, or a combination of wired and wireless connections. Communication interface 914 may permit device 900 to receive information from another device and/or provide information to another device. For example, communication interface 914 may include an Ethernet interface, an optical interface, a coaxial interface, an infrared interface, a radio frequency (RF) interface, a universal serial bus (USB) interface, a Wi-Fi® interface, a cellular network interface, and/or the like.

Device 900 may perform one or more processes described herein. Device 900 may perform these processes based on processor 904 executing software instructions stored by a computer-readable medium, such as memory 906 and/or storage component 908. A computer-readable medium may include any non-transitory memory device. A memory device includes memory space located inside of a single physical storage device or memory space spread across multiple physical storage devices. Software instructions may be read into memory 906 and/or storage component 908 from another computer-readable medium or from another device via communication interface 914. When executed, software instructions stored in memory 906 and/or storage component 908 may cause processor 904 to perform one or more processes described herein. Additionally, or alternatively, hardwired circuitry may be used in place of or in combination with software instructions to perform one or more processes described herein. Thus, embodiments described herein are not limited to any specific combination of hardware circuitry and software. The term “programmed or configured,” as used herein, refers to an arrangement of software, hardware circuitry, or any combination thereof on one or more devices.

Although embodiments have been described in detail for the purpose of illustration, it is to be understood that such detail is solely for that purpose and that the disclosure is not limited to the disclosed embodiments, but, on the contrary, is intended to cover modifications and equivalent arrangements that are within the spirit and scope of the appended claims. For example, it is to be understood that the present disclosure contemplates that, to the extent possible, one or more features of any embodiment can be combined with one or more features of any other embodiment.

What is claimed is

1. A system comprising:
a sensor;
a punch device; and
at least one processor in communication with the sensor and the punch device, the at least one processor configured to:
detect a plurality of fasteners on an object based on the sensor;
determine a location of each fastener of the plurality of fasteners; and
control the punch device to automatically punch through the object with the punch device at each location for each of the plurality of fasteners.

2. The system of claim 1, further comprising an end effector configured to move the punch device in at least three dimensions, the at least one processor further configured to control movement of the end effector to punch through the object at each location.

3. The system of claim 2, wherein the end effector is arranged on a routing machine and/or a robotic arm.

4. The system of claim 1, further comprising a consumable surface arranged below the object, the consumable surface adapted to be punctured by at least a subset of fasteners punched with a punching device.

5. The system of claim 1, further comprising a conveyer belt arranged to convey a plurality of objects including the object across an area, wherein the punch device is arranged to punch objects in the area.

6. The system of claim 1, wherein the at least one processor is further configured to:
generate at least one graphical user interface based on detecting the plurality of fasteners, the at least one graphical user interface comprising visual representations of at least a subset of fasteners of the plurality of fasteners; and
receive user input through the at least one graphical user interface, wherein punching through the object with the punch device is based on the user input.

7. The system of claim 6, wherein the user input comprises a confirmation of a fastener location and/or a rejection of a fastener location, and wherein the object is punched in response to receiving the user input.

8. The system of claim 6, wherein the plurality of fasteners is detected based on a fastener detection model, and wherein the at least one processor is further configured to train the fastener detection model based on the user input.

9. The system of claim 1, wherein the sensor comprises a camera, and wherein the plurality of fasteners is detected based on processing data from the camera with an object detection model.

10. The system of claim 1, wherein the location of each fastener is determined based on calibration data and sensor data received from the sensor.

11. A method comprising:
detecting, with at least one processor, a plurality of fasteners on an object based on sensor data received from a sensor arranged to capture visual data of the object;
determining, with at least one processor, a location of each fastener of the plurality of fasteners based on the sensor data; and
control a punch device to automatically punch through the object with the punch device at each location for each of the plurality of fasteners.

12. The method of claim 11, wherein the punch device is supported by an end effector configured to move the punch device in at least three dimensions, the method further comprising controlling movement of the end effector to punch through the object at each location.

13. The method of claim 12, wherein the end effector is arranged on a routing machine and/or a robotic arm.

14. The method of claim 11, further comprising arranging a consumable surface below the object, the consumable surface adapted to be punctured by at least a subset of fasteners punched with a punching device.

15. The method of claim 11, the method further comprising conveying, with a conveyor belt, a plurality of objects including the object across an area, wherein the punch device is arranged to punch objects in the area.

16. The method of claim 11, the method further comprising:
generating at least one graphical user interface based on detecting the plurality of fasteners, the at least one graphical user interface comprising visual representations of at least a subset of fasteners of the plurality of fasteners; and
receiving user input through the at least one graphical user interface, wherein punching through the object with the punch device is based on the user input.

17. The method of claim 16, wherein the user input comprises a confirmation of a fastener location and/or a rejection of a fastener location, and wherein the object is punched in response to receiving the user input.

18. The method of claim 16, wherein the plurality of fasteners is detected based on a fastener detection model, the method further comprising training the fastener detection model based on the user input.

19. The method of claim 11, wherein the sensor comprises a camera, and wherein the plurality of fasteners is detected based on processing data from the camera with an object detection model.

20. The method of claim 11, wherein the location of each fastener is determined based on calibration data and sensor data received from the sensor.

21. A computer program product comprising at least one non-transitory computer-readable medium including program instructions that, when executed by at least one processor in communication with a sensor and a punch device, cause the processor to:
detect a plurality of fasteners on an object based on a sensor;
determine a location of each fastener of the plurality of fasteners; and
control a punch device to automatically punch through the object with the punch device at each location for each of the plurality of fasteners.
